(19) United States
(12) Patent Application Publication
(10) Pub. No.: US 2020/0043660 A1
(43) Pub. Date: Feb. 6, 2020

(54) CAPACITOR TRIMMING IN A PASSIVES ON INSULATOR PROCESS

(71) Applicant: QUALCOMM Incorporated, San Diego, CA (US)

(72) Inventor: Peter LAASER, Munich (DE)

(21) Appl. No.: 16/055,232

(22) Filed: Aug. 6, 2018

(51) Int. Cl. H01G 4/255; H01G 4/40; H01G 4/018

(52) U.S. Cl. CPC H01G 4/255; H01G 4/018; H01G 4/40

(57) ABSTRACT

Aspects generally relate to a capacitor formed by a first conductive plate and a second conductive plate with an insulating material located between the first and second conductive plates. A third conductive plate is coupled to the second conductive plate, and a size or an overlap of the third conductive layer to the insulating layer and first conductive plate are adjusted to achieve a desired overall capacitance value of the capacitor.

### BACKGROUND

### I. Field of the Disclosure

Aspects of the disclosure relate generally to capacitors on a passives Oil insulator (POI) device, and in particular to adjusting the value of a capacitor in a POI device.

### II. Background

As wireless communication systems continue to evolve there is increasing need to improve performance of radio frequency (RF) devices. For example, in the fifth generation (5G) standard being developed there are stringent bandwidth and attenuation requirements for components such as RF filters. To meet these stringent requirements requires the value of components used in circuitry to be very accurate.

There is a need for mechanisms and methods to produce components with values that are very accurate.

### SUMMARY OF THE DISCLOSURE

The following presents a simplified summary of one or more aspects to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

The described aspects generally relate to a capacitor formed by a first conductive plate and a second conductive plate with an insulating material located between the first and second conductive plates to form the capacitor. A third conductive plate is coupled to the second conductive plate, and a size or an overlap of the third conductive layer to the insulating layer and first conductive plate are adjusted to achieve a desired overall capacitance value of the capacitor, wherein adjusting the size or overlap is based on a measured or estimated capacitance between the first conductive plate and the second conductive plate.

The first, second, and third conductive plates of the capacitor can be metal plate. There can also be a second insulating layer located between the second and third conductive plates. The dielectric value of the second insulating layer can be different from the dielectric value of the first insulating layer. Also, the second insulating layer can be thicker than the first insulating layer.

An area of the first conductive plate of the capacitor can be larger than the area of the second conductive plate. There is an overlap region where the first conductive plate extends beyond the second conductive plate.

An aspect of a passives on insulator device includes an insulator substrate, such as a glass substrate. A MIM capacitor is formed on the substrate. A metal layer is formed over the MIM capacitor, the metal layer being coupled to a plate of the MIM capacitor. An inductor is formed in a metal layer above the metal layer and coupled to the metal layer. The size of the metal layer can be selected to achieve a desired capacitance value of the MIM capacitor and metal layer combination, wherein the selection of the size of the metal layer is based on a measured or estimated capacitance between the first conductive plate and the second conductive plate of the MIM capacitor. There can also be an insulating layer between the MIM capacitor and metal layer. A dielectric value of the insulating layer between the MIM capacitor and the metal layer can be different than the dielectric layer of the MIM capacitor.

The passives on insulator device with the MIM capacitor, the metal layer, and the inductor can form a radio frequency (RF) filter. For example, the RF filter can be a 5G RF filter.

An additional aspect is a method of fabricating a capacitor. The method includes forming a first conductive plate and forming an insulating layer on the first conductive plate. Forming a second conductive plate on a surface of the insulating layer opposite the first conductive plate. Forming a third conductive plate coupled to the second conductive plate and adjusting a size or an overlap of the third conductive plate, with the first conductive plate and insulating layer, to achieve a desired overall capacitance value of the capacitor.

Adjusting the size or overlap can be accomplished by selecting a mask from a set of prepared masks to form the third conductive plate. Adjusting the size or overlap can be based on a measured or estimated capacitance between the first conductive plate and the second conductive plate.

Aspects also include a method of fabricating a passives on insulator device by forming a MIM capacitor on an insulating substrate. A metal layer is formed over the MIM capacitor, the metal layer coupled to a plate of the MIM capacitor, An inductor is formed in a metal layer above the metal layer, the inductor is coupled to the metal layer. The size of the metal layer can be selected to achieve a desired capacitance value of the MIM capacitor and metal layer combination, wherein the selection of the size of the metal layer is based on a measured or estimated capacitance between the first conductive plate and the second conductive plate of the MIM capacitor. An aspect includes the MIM capacitor, the metal layer, and the inductor form a radio frequency (RF) filter. For example, a 5G RF filter.

Various aspect and features of the disclosure are described in further detail below.

### BRIEF DESCRIPTION OF THE FIGURES

The accompanying drawings are presented to aid in the description and illustrations of embodiments and are not intended to be limitations thereof.

FIGS. 1A and 1B are a top view and side view of an example MIM capacitor in a POI device.

FIGS. 2A and 2B are a top view and side view of an example MIM capacitor in a POI device.

FIGS. 3A and 3B are a top view and side view of another example MIM capacitor in a POI device.

FIGS. 4A and 4B are a top view and side view of another example MIM capacitor in a POI device.

FIGS. 5A and 5B are a top view and side view of another example MIM capacitor in a POI device.

FIG. 6 is a cross section of an example RF filter on a POI.

FIG. 7 is a flow chart illustrating a method of forming a capacitor.

The drawings may not depict all components of a particular apparatus, structure, or method. Further, like reference numerals denote like features throughout the specification and figures.

### DETAILED DESCRIPTION

Aspects disclosed in the following description and related drawings are directed to specific embodiments. Alternative embodiments may be devised without departing from the scope of the invention. Additionally, well-known elements may not be described in detail, or may be omitted, so as not to obscure relevant details. Embodiments disclosed may be suitably included in any electronic device.

With reference now to the drawing, several exemplary aspects of the present disclosure are described. The word “exemplary” is used herein to mean “serving as an example, instance, or illustration.” Any aspect described herein as “exemplary” is not necessarily to be construed as preferred or advantageous over other aspects. Furthermore, the terminology used herein is for the purpose of describing particular embodiments and is not intended to be limiting

In a wireless communication system, such as 5G, there are stringent bandwidth and attenuation requirements for RF filter. RF filters can be implemented using discrete inductor and capacitor components in different types of processes, for example on a Passives on Insulator (POI) such as Passives on Glass (POG), Low Temperature Co-fired Ceramic (LTCC), High Temperature Co-fired Ceramic (HTCC), or other types of process technology.

In POI technology, capacitors can be implemented as metal-insulator-metal (MIM) capacitors. A MIM capacitor is formed by a vertical metal-insulator-metal layer stack that form conductive plates of the capacitor separated by a dielectric material. Inductors for the filter can be implemented by metal lines forming a circle or a spiral structure.

The performance characteristics of an RF filter, for example, in-band insertion loss, out-of-band attenuation, reflection factor at the input and output terminal, etc., depend on the absolute value of the implemented inductors and capacitances. For example, it may be required that the value of the capacitances and inductors match the expected value within an accuracy in the order of +/−2% in order to meet performance requirements.

Making components that have values within these high accuracy requirements is challenging due to process variations during fabrication of the components. Due to process variations the absolute value of inductors and capacitances varies causing significant impact on the yield and cost of filter devices implemented in POI processes. As described further below, aspects include adjusting the absolute value of capacitors implemented in POI devices to significantly increase the yield and to reduce the cost of RF filter devices using POI technology.

One technique typically used to “trim” a capacitor to a desired value is to have multiple trimming capacitors that can be added in series or parallel with a main capacitor to increase or decrease the capacitance to a desired value. One drawback to this technique is that the trimming capacitors, even if not used, are still present on the device increasing the overall size of the device. Also, the trimming capacitors increase unwanted electrical parasitics and can have a negative impact on the transfer function of a filter. On the contrary, due to the high frequency used in 5G, the trimming capacitor may need to be very small, on the order of 0.05-0.1 pF, which are difficult to fabricate.

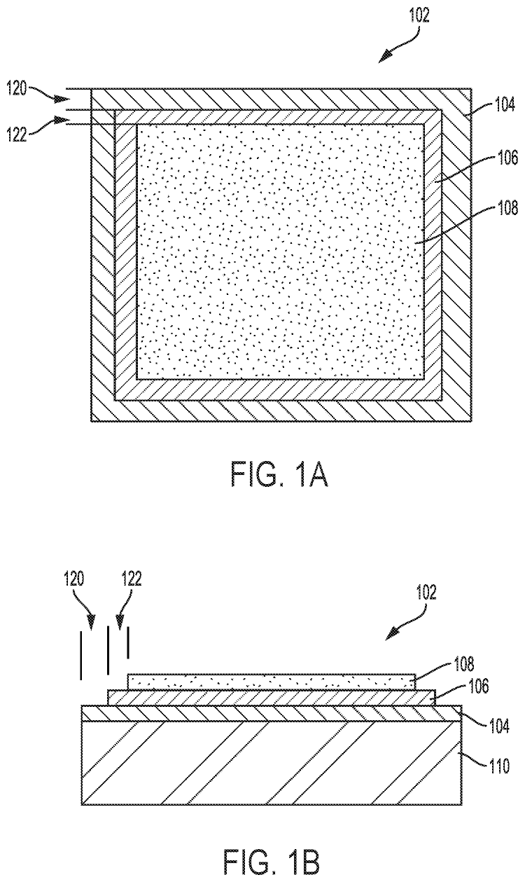

FIGS. 1A and 1B are a top view and side view of an example MIM capacitor in a POI device. As shown in FIG. 1A, a MIM capacitor 102 can be implemented with a first metal layer 104, an insulating layer 106 and a second metal layer 108. In general, the metal layers form plates of a capacitor and can be fabricated with any conductive material. FIG. 1B illustrates that the MIM capacitor 102 is implemented on an isolating substrate 110, for example, a glass substrate.

In FIGS. 1A and 1B the first metal layer 102 and second metal layer 108 form the plates of the MIM capacitor 102. Between the first and second metal layer, 104 and 106 respectfully, is the insulating layer 106 that is the dielectric of the capacitor. In the example of FIGS. 1A and 1B, the first metal layer 104, insulating layer 106, and second metal layer 108 are generally rectangular shapes. The insulating layer 106 is smaller than the first metal layer 104 resulting in a first overlap region 120. The second metal layer 108 is smaller than the insulating layer 106 resulting in a second overlap region 122. The first and second overlap regions 120 and 122 help ensure that there will not be an electrical short between the first and second metal layers, 104 and 108, due to process variations.

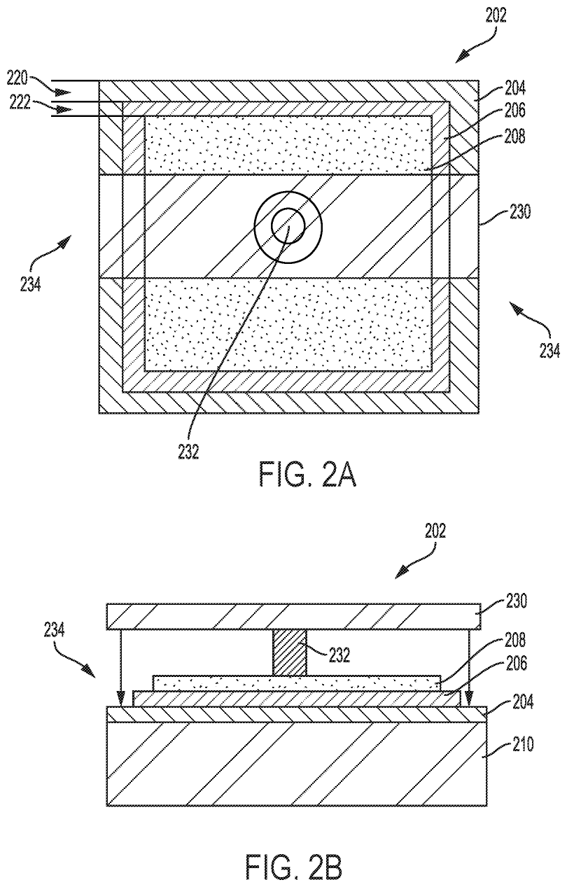

FIGS. 2A and 2B are a top view and side view of an example MIM capacitor in a POI device. The MIM capacitor 202 of FIGS. 2A and 2B, similar to FIGS. 1A and 1B, includes a first metal layer 204 forming a conductive plate, first insulating layer 206, and second metal layer 208 forming a conductive plate. The insulating layer 206 is smaller than the first metal layer 204 resulting in a first overlap region 220. The second metal layer 208 is smaller than the insulating layer 206 resulting in a second overlap region 222.

As shown in FIGS. 2A and 2B, the MIM capacitor 202 includes a third metal layer 230 coupled to the second metal layer 208 by a via 232. There is an insulating layer between the second and third metal layer, 208 and 230, not shown for clarity. The shape of the third metal layer 230 can be controlled such that it extends over a portion 234 of the first metal layer 204 and first insulating layer 206. By coupling the third metal layer 230 to the second metal layer 208, the portion of the third metal layer 230 that extends over the insulating layer 206 and first metal layer 204 increases or decreases the effective size of the plates of the MIM capacitor 202 and thereby increases or decreases the capacitance.

The size of the third metal layer 230 can be controlled to obtain a desired capacitance for the MIM capacitor 202. For example, before the third metal layer 230 is formed the capacitance between the first and second metal layer 204 and 208 can be measured or estimated. Based on the measured or estimated capacitance a mask that will be used to form the third metal layer 230 can be selected. In one embodiment, the mask selected can be from a set of prepared masks. In another embodiment, a mask can be made with the desired dimensions for the third metal layer 230. In yet another embodiment, the third metal layer can be formed lager than a desired finished size and then trimmed, for example, by etching, etc., to achieve a desired size.

In one embodiment, the desired capacitance of the MIM capacitor 202 can be designed such that in nominal case it includes at least a portion of the third metal layer 230 extending over at least a portion 234 of the first metal layer 204 and first insulating layer 206. If the measured capacitance of the MIM capacitor 202 is too large, the size of the third metal layer overlapping the first metal layer 204 and insulating layer 206 can be decreased.

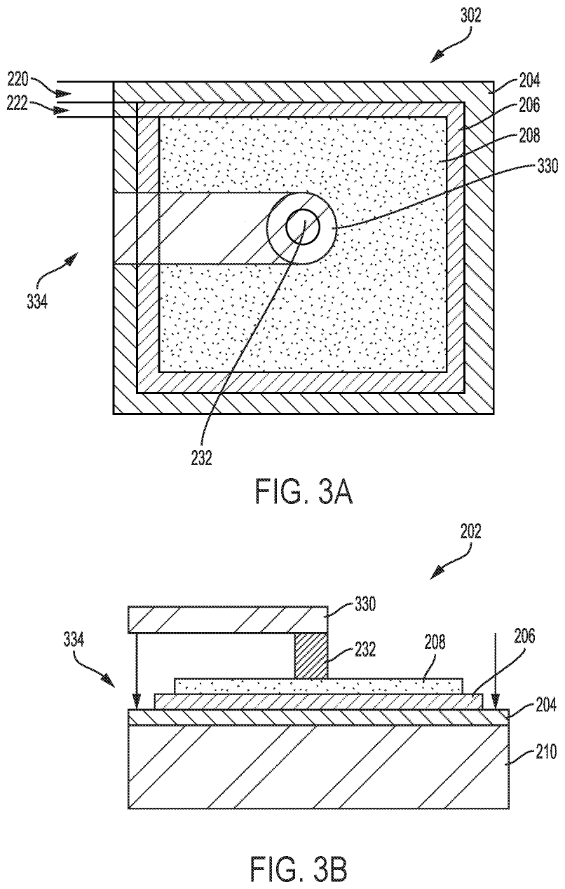

FIGS. 3A and 3B are a top view and side view of another example MIM capacitor in a POI device. The MIM capacitor 302 of FIGS. 3A and 3B is similar to FIGS. 2A and 2B. As shown in FIGS. 3A and 3B the third metal layer 330 is smaller than the third metal layer 230 in FIGS. 2A and 2B. The smaller area of the third metal layer 330 in FIGS. 3A and 3B overlap extends over a smaller portion 334 of the first metal layer 204 and first insulating layer 206 than the overlap region 234 in FIGS. 2A and 2B. Reducing the area of the overlap region 306 results in a decreased capacitance compared to the capacitor 202 illustrated in FIGS. 2A and 2B.

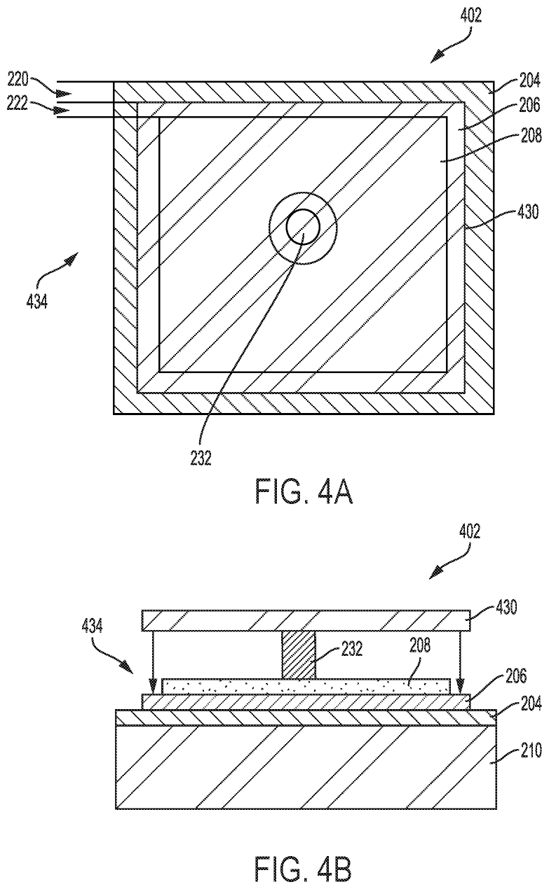

FIGS. 4A and 4B are a top view and side view of another example MIM capacitor in a POI device. The MIM capacitor 402 of FIGS. 4A and 4B is similar to FIGS. 2A and 2B. As shown in FIGS. 4A and 4B the third metal layer 430 is larger than the third metal layer 230 in FIGS. 2A and 2B. The third metal layer 430 in FIGS. 4A and 4B is about the same size as the insulating layer 206. The larger area of the third metal layer 430 in FIGS. 4A and 4B overlap extends over a larger portion 434 of the first insulating layer 206 than the overlap region 234 in FIGS. 2A and 2B. Increasing the area of the overlap region 434 results in an increase capacitance compared to the capacitor 202 illustrated in FIGS. 2A and 2B.

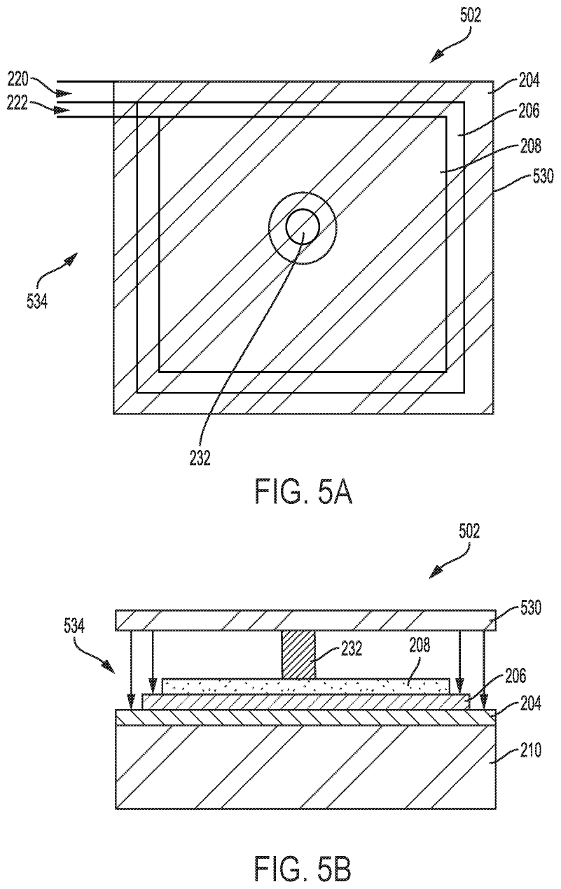

FIGS. 5A and 5B are a top view and side view of another example MIM capacitor in a POI device. The MIM capacitor 502 of FIGS. 5A and 5B is similar to FIGS. 2A and 2B. As shown in FIGS. 5A and 5B the third metal layer 530 is larger than the third metal layer 230 in FIGS. 2A and 2B. The third metal layer 530 in FIGS. 5A and 5B is about the same size as the first metal layer 204. The larger area of the third metal layer 530 in FIGS. 5A and 5B overlap extends over a larger portion 534 of the first metal layer 204 and first insulating layer 206 than the overlap region 234 in FIGS. 2A and 2B. Increasing the area of the overlap region 434 results in an increase, approximately a maximum value of, capacitance compared to the capacitor 202 illustrated in FIGS. 2A and 2B.

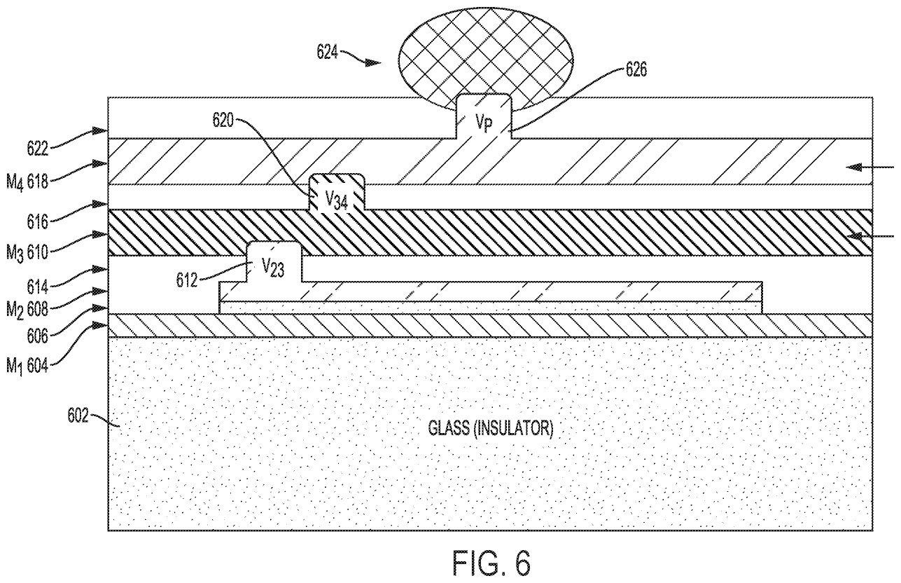

FIG. 6 is a cross section of an example RF filter on a POI. In the example of FIG. 6 there is a insulator substrate 602, such as a glass substrate. On a surface of the substrate 602 there is a first metal layer 604, a first insulating layer 606, and a second metal layer 608 forming a MIM capacitor. A third metal layer 610 is coupled to the second metal layer 608 by a via 612. The third metal layer 610 can be sized, as described above with FIGS. 2-5, to adjust the value of capacitance of the MIM capacitor. A second insulating layer 614 between the second metal layer 608 and third metal layer 610 forms a dielectric layer of a capacitance between the third metal layer 610 and the first metal layer 604. The dielectric constant and/or thickness of the second insulating layer 614 can be adjusted to get a desired capacitance value.

A third insulating layer 616 is formed above the third metal layer 610. Above the third insulating layer 616 is a fourth metal layer 618. In the fourth metal layer 618 an inductor is formed, for example a circular or spiral shaped inductor. The MIM capacitor is coupled to the inductor by a second via 620. Above the fourth metal layer 618 there is a passivation layer 622 to protect the POI device. A solder ball 624 is coupled to the fourth metal layer 618 by a third vis 626. The solder ball 624 provides input/output connection to devices external to the POI device. There are additional solder balls, not shown, to provide additional input/output for the POI device. In addition, there are additional connections and vias between the various layers of the POI that are not shown for clarity issues.

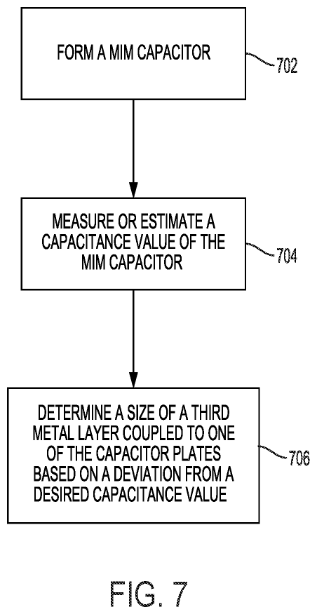

FIG. 7 is a flow chart illustrating a method of forming a capacitor. Flow begins in block 702 where a MIM capacitor is formed using two metal layers separated by an insulating layer. In one embodiment, the insulating layer has a small thickness to achieve a high sheet capacitance and a small form factor of the capacitance. To prevent electrical shorts between the first and second metal layers due to geometric variations in the fabrication of the metal and insulating layers the two metal layers are different sizes so that there is an overlap region, as described above.

Flow continues to block 704 where a capacitance value of the MIM capacitor, already formed, is measured. In another embodiment, not all capacitors formed on a wafer are measured, instead a subset of capacitors is measured, and the measured values can be used to interpolate values of other capacitors on the wafer. Various techniques can be used to measure the capacitance, for example, test probes can be used to couple to the capacitor to measure the capacitance, or optical measurements of the size of the MIM capacitor plates formed by the metal layers can be used to estimate the capacitance.

Flow continues to block 706 where, based on a deviation of the measured capacitance value from a desired capacitance value, the size of a third metal layer is determined. The third metal layer will be coupled to the second metal layer and overlap with the insulating layer and first metal layer to adjust the effective capacitance of the MIM capacitor and third metal layer combination. The size of the third metal layer, and the amount of overlap, can be controlled in various ways, for example the third metal layer can be formed using a mask fabricated to get a desired size of the third metal plate. In addition, a mask can be selected from a set of prepared masks that will form a desired third metal layer, or a third metal layer can be formed and then laser trimmed to a desired size.

As described above, aspects include capacitor trimming to compensate for geometrical or chemical variations of the POI process. An aspect is not to trim the size of the plates of the MIM capacitor (M1 and M2), which could be done but would be expensive. As described, instead of trimming the plates of the MIM capacitor, the size of an additional metal layer, which is not yet processed, is coupled to one of the plates of the MIM capacitor. Adjusting the size or overlap of the third metal layer the effective capacitor value can be varied to compensate for process variations.

While the above description gave some specific examples variations to the examples described can also be implemented. For example, in the description about the MIM capacitor is described as being form using the first and second metal layers, but the capacitor can be implemented in any of the metal layers in a device. In general aspects include a MIM capacitor that is already processed, and a metal layer that still has to be processed. The metal layer to be processed is coupled to one of the MIM capacitor plates. The size or overlap of the metal layer to be processed and, coupled to one of the MIM capacitor plates, and the other MIM capacitor plate is based on a capacitance value of the already processed MIM capacitor.

In addition, aspects can be applied to capacitors other than MIM capacitors. For example, instead of using metal layers for the plates of the capacitor, plates of the capacitor can be formed using any conductive material, such as, a low-ohmic poly-resistor layer.

The various illustrative logical blocks, modules, and circuits described in connection with the aspects disclosed herein may be implemented or performed in an integrated circuit (IC), a system on a chip (SoC), an Application Specific Integrated Circuit (ASIC), a Field Programmable Gate Array (FPGA) or other programmable logic device, discrete gate or transistor logic, discrete hardware components, or any combination thereof designed to perform the functions described herein.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in flow chart diagrams may be subject to numerous different modifications as will be readily apparent to one of skill in the art.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. A capacitor comprising:
a first conductive plate and a second conductive plate;
an insulating material located between the first and second conductive plates to form a capacitor; and
a third conductive plate coupled to the second conductive plate, a size or an overlap of the third conductive layer adjusted to achieve a desired overall capacitance value of the capacitor, wherein adjusting the size or overlap is based on a measured or estimated capacitance between the first conductive plate and the second conductive plate.

2. The capacitor of claim 1, wherein the first, second, and third conductive plates are metal.

3. The capacitor of claim 1, further comprising a second insulating layer located between the second and third conductive plates.

4. The capacitor of claim 3, wherein a dielectric value of the second insulating layer is different from a dielectric value of the first insulating layer.

5. The capacitor of claim 3, wherein the second insulating layer is thicker than the first insulating layer.

6. The capacitor of claim 1 wherein the area of the first conductive plate is larger than the area of the second conductive plate.

7. The capacitor of claim 6, wherein there is an overlap region where the first conductive plate extends beyond the second conductive plate.

8. A passives on insulator device, comprising:
an insulator substrate;
a MIM capacitor formed on the substrate;
a first metal layer formed over the MIM capacitor, the first metal layer coupled to a plate of the MIM capacitor; and
an inductor formed in a second metal layer above the first metal layer and coupled to the first metal layer.

9. The device of claim 8, wherein a size of the first metal layer is selected to achieve a desired capacitance value of the combination of the MIM capacitor and first metal layer, wherein the selection of the size of the metal layer is based on a measured or estimated capacitance between the first conductive plate and the second conductive plate of the MIM capacitor.

10. The device of claim 8, further comprising an insulating layer between the MIM capacitor and the first metal layer.

11. The device of claim 10, wherein a dielectric value of the insulating layer between the MIM capacitor and the first metal layer is different than a dielectric layer of the MIM capacitor.

12. The device of claim 8, wherein the MIM capacitor, the first metal layer, and the inductor form a radio frequency (RF) filter.

13. The device of claim 12, wherein the RF filter is a 5G RF filter.

14. A method of fabricating a capacitor, the method comprising:
forming a first conductive plate;
forming an insulating layer on the first conductive plate
forming a second conductive plate on a surface of the insulating layer opposite the first conductive plate; and
forming a third conductive plate coupled to the second conductive plate and adjusting a size or an overlap of the third conductive plate, with the first conductive plate and insulating layer, to achieve a desired overall capacitance value of the capacitor.

15. The method of claim 14, wherein adjusting a size or overlap comprises selecting a mask from a set of prepared masks to form the third conductive plate.

16. The method of claim 14, wherein adjusting a size or overlap is based on a measured or estimated capacitance between the first conductive plate and the second conductive plate.

17. A method of fabricating a passive on insulator device, comprising:
forming a MIM capacitor on an insulating substrate;
forming a first metal layer over the MIM capacitor, the first metal layer coupled to a plate of the MIM capacitor; and
forming an inductor in a second metal layer, the inductor coupled to the first metal layer.

18. The method of claim 17, wherein a size of the first metal layer is selected to achieve a desired capacitance value of the MIM capacitor and first metal layer combination, wherein the selection of the size of the first metal layer is based on a measured or estimated capacitance between the first conductive plate and the second conductive plate of the MIM capacitor.

19. The method of claim 17, wherein the MIM capacitor, the first metal layer, and the inductor form a radio frequency (RF) filter.

20. The method of claim 19, wherein the RF filter is a 5G RF filter.
